(19) United States
(12) Patent Application Publication
(10) Pub. No.: US 2022/0365380 A1
(43) Pub. Date: Nov. 17, 2022

(54) OPTICAL INSTRUMENT AND METHOD FOR DETERMINING A WAVELENGTH OF LIGHT GENERATED BY A LIGHT SOURCE, AND OPTICAL SYSTEM COMPRISING THE OPTICAL INSTRUMENT

(71) Applicant: ROCKLEY PHOTONICS LIMITED, Altrincham (GB)

(72) Inventors: Trevor FOWLER, Los Angeles, CA (US); Richard GROTE, Rancho Cucamonga, CA (US); Miguel Ángel GUILLÉN-TORRES, Los Angeles, CA (US); Caroline LAI, Sierra Madre, CA (US); Haydn Frederick JONES, London (GB)

(21) Appl. No.: 17/743,427

(22) Filed: May 12, 2022

Related U.S. Application Data
(60) Provisional application No. 63/188,390, filed on May 13, 2021.

(51) Int. Cl. G02F 1/11; H01S 3/106

(52) U.S. Cl. CPC G02F 1/116; H01S 3/1068

(57) ABSTRACT

The invention refers to an optical instrument for determining a wavelength of light generated by a light source, comprising a signal generator for generating a modulation signal, a tunable optical filter device configured to receive the modulation signal, the tunable optical filter device configured to modulate the light generated by the light source based on the modulation signal, an optical detector device configured to detect a degree of modulation of light modulated by the tunable optical filter device, and an analyser configured to determine the wavelength of the light based the degree of modulation.

The present application claims priority to and the benefit of U.S. Provisional Application No. 63/188,390, filed May 13, 2021; the entire contents of all of the documents identified in this paragraph are incorporated herein by reference.

The present disclosure relates to an optical instrument for determining a wavelength of light generated by a light source, comprising a tunable optical filter device configured to receive the modulation signal, wherein the tunable optical filter device is configured to modulate the light generated by the light source. The present disclosure further relates to an optical system, comprising the optical instrument and a light source generating light which is input into the tunable optical filter device. The present disclosure also relates to a method for determining a wavelength of light generated by a light source, comprising the step of modulating the light generated by the light source.

### BACKGROUND

Determining the wavelength of a laser is one of the most critical experiments required for initial or regular device validation. Lasers are required to have stable output over both short and long time periods in both wavelength and intensity for many applications. Characterizing these properties is even more critical and difficult when a laser is operating in a pulsed mode, where the laser is turned on and off with a known period and duty cycle. This is due to the complex interplay between the quantum mechanics determining the generation of light via stimulated emission and the thermal dynamics of the substrate. Since these lasers are often switched on for relatively short periods of time (typically in the microsecond regime), it becomes critical to make extremely fast wavelength measurement to determine dynamics and settling time of such a device.

### SUMMARY

Accordingly, some embodiments of the present invention aim to solve the above problems by the subject matter of the independent claims.

Some embodiments of the invention described herein refer to an optical instrument and/or a method for making accurate wavelength measurements over very short time scales using acousto-optic tunable filters (AOTFs). These devices can utilize specialized birefringent crystals such as lithium niobate or tellurium dioxide which, when excited by an RF signal, establish refractive index patterns that act as diffraction gratings for light of specific polarization orientation, filtering out and allowing to track the optical frequency of a device under test (DUT) such a laser or an apparatus including a laser.

Some embodiments of the invention allow for the determination of wavelength (optical frequency) over extremely large wavelength ranges (in this case, between 1400-2400 nm, but can be expanded by using different acousto-optic tunable filters).

Some embodiments of the invention allow for the determination of optical frequency at high rates (˜25-50 microsecond resolution).

Some embodiments of the invention allow these measurements to be interpolated with a pulsed DUT (improving time resolution to 5-10 microseconds).

Filter linewidth can be improved by double-passing the optical path through the AOTF as described herein.

Filter linewidth can be improved by using multiple AOTFs as described herein.

A first aspect of this disclosure relates to an optical instrument for determining a wavelength of light generated by a light source, comprising a signal generator for generating a modulation signal, a tunable optical filter device configured to receive the modulation signal, the tunable optical filter device configured to modulate the light generated by the light source based on the modulation signal, an optical detector device configured to detect a degree of modulation of light modulated by the tunable optical filter device, and an analyser configured to determine the wavelength of the light based the degree of modulation.

A second aspect of this disclosure relates to an optical system, comprising the optical instrument, and a light source generating light which is input into the tunable optical filter device.

A third aspect of this disclosure relates to a method for determining a wavelength of light generated by a light source, comprising the steps of a) generating a modulation signal, b) modulating the light generated by the light source based on the modulation signal, c) detecting a degree of modulation of the modulated light, and d) determining the wavelength of the light based on the degree of modulation.

Aspects of some embodiments of the invention can be summarized as follows:
Method for the determination of the instantaneous wavelength of a light source
   Using AOTF based acoustic frequency scans.
Optical instrument used to determine the instantaneous wavelength of a light source
   Using AOTF based acoustic frequency scans and/or
   Utilizing time delays to improve time resolution of frequency measurements.
Optical instrument to determine the wavelength of a light source over a large bandwidth
   Using AOTF based acoustic frequency scans and/or
   Utilizing AOTF double-pass geometry to improve optical filter performance and/or
   Utilizing multiple AOTFs to improve optical filter performance.

The light source may be the DUT which can include an output port through which the (laser) light generated by the laser of the light source exits the light source. Alternatively, the light source can be opened to access the output port or the light itself. The optical instrument or a tunable optical filter device thereof is configured to be coupled to the output port or to be put in the light within the light source so that the light impinges on the tunable optical filter device. For example, the optical instrument may include light guiding means such as an optical fibre and/or mirrors for conveying the light generated by the light source from the output port to the tunable optical filter device.

The light source may be configured to generate light of a fixed wavelength, in particular a wavelength which is constant over time. The light source may include one or more lasers and/or one or more light emitting diode (LED). The light generated by these devices exits the light source at the output port her optional features of the invention are set out below.

The optical instrument and the method may be used to determine the wavelength of the light generated by the light source and/or whether the wavelength of the light generated by the light source is constant over time. To this end, the measurements executed by the optical instrument or the method can be repeatedly executed to determine a time behavior of the wavelength of the light generated by the light source. The optical instrument may be considered as a test or validation instrument for the light source.

The optical instrument may include a housing and/or an input port which is configured to couple in the light generated by the light source. The input port may be coupled to the output port of the light source by means of a light conveying device, such as a waveguide, a mirror and/or an optical fibre. The input port may include a transparent window and/or a cavity in the housing through which the light generated by the light source can propagate. The optical instrument may include means for conveying the light from the input port to the tunable optical filter device, such as a waveguide, a mirror, and/or an optical fibre. Alternatively or additionally, there is a free space between input port and the tunable optical filter device such that light that enters the optical instrument wire the input port can impinge on the tunable optical filter device. In general, the optical instrument allows the propagation of light from the input port to tunable optical filter device. This means that the light generated by the light source can impinge on tunable optical filter device.

The tunable optical filter device is electrically and/or electronically coupled or connected to the signal generator and is configured to receive the modulation signal that is generated by the signal generator. The tunable optical filter device is configured to modulate the light impinging on the tunable optical filter device based on or according to the modulation signal. This means, a degree of modulation provided by the tunable optical filter device depends on the modulation signal. A variation of the modulation signal results in a variation of the degree of modulation of the light impinging on the tunable optical filter device. For example, the tunable optical filter device changes the direction of propagation of the light exiting the tunable optical filter device depending on the modulation signal. This may be achieved by diffraction so that the modulation signal changes the diffraction characteristics of the tunable optical filter device. In general, a change in the modulation signal results in a change of a parameter (such as the direction) of propagation of the light leaving a tunable optical filter device.

The tunable optical filter device is an electrical component that is capable of changing a parameter, such as the frequency, wavelength, phase, etc., and/or the direction of propagation of light being modulated by the tunable optical filter device. Thus, the tunable optical filter device is configured to convert the information included in the modulation signal into a change in the light that is modulated by the tunable optical filter device.

The optical instrument may include optical means for conveying the light modulated by the tunable optical filter device to the optical detector device. For example, a free space or a cavity is provided between the tunable optical filter devise an optical detector device. Alternatively or additionally, mirrors or other optical components for directing the light that is modulated by the tunable optical filter devise to the optical detector device can be provided.

The optical detector device includes means for detecting the degree of modulation and converting the detected degree of modulation into an electronic signal that can be forwarded to the analyser. For example, if the modulation of the light guide tunable optical filter device results in a change in the direction of propagation of the modulated light, the optical detector device may be configured to spatially resolve or to detect a change in the orientation of the modulated light. Alternatively or additionally, the optical detector device may be configured to detect an intensity of the modulated light which can be indicative of the degree of modulation.

The analyser can be electronically or electrically connected or coupled to the optical detector device for receiving the electronic or electric signal that is generated by the optical detector device and indicative of the degree of modulation. The analyser may include one or more processing means, a memory, and/or other electrical or electronic components for analyzing the received electronic or electrical signals. For example, the analyser may store and execute an algorithm and/or program for analyzing the received electronic or electrical signal. This algorithm and/or program is configured to extract the wavelength of the light modulated by the tunable optical filter device from the electronic or electric signal is generated by an optical detector device based on the light by the tunable optical filter device. The analyser may be a computer that is connected to the optical detector device.

The signal generator may be a means for generating an electric or electronic signal. The signal generator is electrically or electronically connected or coupled to the tunable optical filter device and/or to the analyser. The modulation signal may be any electronic or electric signal that can be processed by the tunable optical filter devise and results in a change in the degree of modulation provided by the tunable optical filter device. The signal generator may generate a base signal (such as a wave having a constant frequency). A parameter of the base signal is changed by the signal generator. Both the base signal and the change in the parameter provide the modulation signal. For example, the modulation signal is an alternating current (base signal) whereby the frequency of the alternating current changes.

In an optional embodiment, the tunable optical filter device includes an acousto-optic tunable filter (AOTF) and/or the tunable optical filter device is configured to diffract the light generated by the light source based on the modulation signal.

The acousto-optic tunable filter may be considered an acousto-optic modulator (AOM), also called a Bragg cell or an acousto-optic deflector (AOD). The acousto-optic tunable filter uses the acousto-optic effect to diffract and shift the frequency of light using sound waves. The frequency, phase, and/or amplitude of the sound waves can be set by the modulation signal. For example, the modulation signal is directly converted into the sound waves by the tunable optical filter device. The change in the diffraction based on the modulation signal may result in a change of the direction of the modulated light and/or the amplitude/intensity of the modulated light at a given position on the optical detector device.

In an optional embodiment, the signal generator generates the modulation signal which includes a sweep of a parameter of the modulation signal for determining the wavelength of the light, wherein the degree of modulation by the tunable optical filter device is highest if the wavelength of the light corresponds to a particular value of the parameter of the modulation signal.

The sweep of the parameter can be a continuous, constant, or steady change in the parameter of the modulation signal. For example, the frequency of the wave generated by the signal generator is continuously or steadily changed providing a sweep of the frequency of the wave (base signal). However, there is also possible to continuously or steadily changed the amplitude of the wave. It is solely necessary that the change in the parameter of the modulation signal (such as the frequency, amplitude, and/or phase) results in a change in the degree of modulation of the light modulated by the tunable optical for the device. In particular, the degree of modulation reaches a maximum or minimum if the wavelength of the light impinging on the tunable optical filter device corresponds to a single value of the parameter of the modulation signal within the range of the sweep. This means the degree of modulation exhibits a minimum and maximum when sweeping the parameter of the modulation signal. This minimum or maximum of the degree of modulation can be detected by optical detector device. In other words, the minimal or maximal degree of modulation occurs at a single wavelength of the light impinging on the tunable optical filter device. Thus, the detection of the minimal or maximal degree of modulation can be used for determining the single wavelength if the relationship between this single wavelength and the minimal or maximal degree of modulation is known.

In an optional embodiment, the signal generator generates the modulation signal which is a frequency-modulated wave whose frequency is swept from a minimum frequency to a maximum frequency. Further optionally, a nominal frequency of the wave is greater than 1 GHz and/or a frequency of the sweep is between 50 MHz to 200 MHz.

The nominal frequency corresponds to the base signal. The change in the frequency results in a change of the sound wave generated by the acousto-optic tunable filter. The sound wave basically provides a diffraction grating in a crystal of the acousto-optic tunable filter so that a change in the frequency of the sound wave induced by the frequency sweep results in a change in the periodicity of the diffraction grating. As a result, the wavelength of the diffracted light changes. This change can be detected by monitoring the amplitude of the modulated light at a certain location. Thus, a sweep of the frequency results in a change in the amplitude of the modulated light at a certain location.

In an optional embodiment, the signal generator includes an arbitrary waveform generator. Optionally, the arbitrary waveform generator is configured to generate a wave whose frequency can be swept (continuously changed) between a minimal frequency and a maximal frequency.

In an optional embodiment, the signal generator is configured to generate a trigger signal simultaneous to the generation of the modulation signal for indicating a start of the modulation signal. The trigger signal may be a pulse that is generated when the sweep of the frequency is started. In other words, the pulse is emitted at the same time as the start of the sweep of the frequency. Alternatively, the trigger signal may be generated as long as the frequency is swept so that a start of the trigger signal coincides with the start of the sweep of the frequency and the end of trigger signal coincides with the end of the sweep of the frequency. For example, the start of the trigger signal coincides with the generation of the minimal frequency and the end of the trigger signal coincides with the generation of the maximal frequency of the sweep of frequencies (or vice versa).

In an optional embodiment, the signal generator is configured to be coupled to the light source, wherein the signal generator is configured to supply the trigger signal to the light source for starting the generation of a light pulse.

For example, the signal generator may include a first signal port to which a cable or wire can be connected which in turn is connected to the light source. In this way, the trigger signal can be used to start the generation of light by the light source. For example, if the trigger signal is a pulse, the light source starts the generation of flight when receiving the trigger signal. Alternatively, the light source generates light as long as the trigger signal is received if the trigger signal is generated as long as the modulation signal is generated.

In an optional embodiment, the signal generator is coupled to the analyser for supplying the trigger signal to the analyser. For example, the signal generator may include a second signal port to which a cable or wire can be connected which in turn is connected to the analyser. This allows the analyser to detect when the modulation signal is started and/or during which period of time the modulation signal is generated.

In an optional embodiment, the analyser includes a calibration means configured to determine the value of the parameter based on the trigger signal. For example, the calibration means is configured to store a relationship between the wavelength of a light and the time since the generation of the trigger signal. Optionally, the calibration means includes a memory storing the relationship, wherein further optionally the relationship is linear function.

The calibration means can be a functional unit of the analyser. For example, the calibration means can be a separate algorithm and/or program that can be executed and stored by the analyser. The calibration means is provided for calibrating the relationship between the wavelength of a light (that may be generated by a calibrated laser source different to the light source or DUT) and the time elapsed since the start of the modulation signal. Thus, the calibration means allows to the analyser to identify the wavelength of the light source solely based on the time elapsed since the start of the generation of the modulation signal. The relationship may include time delays or time lags inherent to the component of the optical instrument.

For example, the calibration means stores various time points of maximum intensity of the degree of modulation of the light modulated by the tunable optical filter device having a known wavelength in relation to the time delay since the start of the modulation signal. The relationship may be stored as a table or a mathematical function. There may be a linear dependency between the degree of wavelength and the time since the start of the modulation signal. To this end, the trigger signal can be used to exactly determine the start of the modulation signal. This relationship may then be used to determine the wavelength in that it firstly determined when the maximum or minimum value of diffraction was recorded since the start of the modulation signal and, secondly, the relationship is used to determine the wavelength based on this determined period of time. The relationship may be interpolated.

In other words, the calibration means can be configured to store a relationship linking the amplitude/intensity of the light and, therefore, the wavelength of the light to the time that has elapsed since the start of the sweep, i.e., since receiving the trigger signal. In this embodiment, a continuous sweep (i.e., continuous change in the frequency of the wave) is assumed. Based on this assumption, the frequency of the sweep is not determined, stored, or used. Rather, the intensity of the modulated light is linked to the time elapsed which corresponds to frequency of the wave.

The relationship may include a delay time between the generation of the trigger signal and the actual start of the sweep. This delay may be caused by the response time of the tunable optical filter device. Assuming a linear relationship, the delay can be regarded as a shift of the linear curve along the temporal or frequency axis.

In an optional embodiment, the optical detector device includes a first photodiode which is positioned to detect first-order diffracted light. Optionally, the first photodiode is configured to measure an intensity of the first-order diffracted light and to supply the measured intensity to the analyser.

A photodiode can be a semiconductor p-n junction device that converts light into an electrical current. The current is generated when photons are absorbed in the photodiode. Thus, a maximum of the current corresponds to a maximum of first-order diffracted light. This maximum of diffracted light with respect to the frequency of the sweep or the time elapsed can be used to determine the wavelength of the light generated by the light source using the relationship stored in the calibration means.

Photodiodes usually have a small detector area so that the current or signal generated by the photodiode strongly varies depending on the degree of diffraction of the modulated light. This allows to precisely detect changes in the modulation of the modulated light. The photodiode thus detects the intensity of modulated light at a particular angle. Variations of the intensity of the modulated light at this particular angle can be reliably and precisely detected. For example, the first photodiode is located at a position within an angular range that corresponds to the angles of the first-order diffracted light which are generated by the frequency sweep.

The first photodiode or the optical detector device is fixed with respect to the tunable optical filter device. The position of the first photodiode within the angular range defines the location of the maximum intensity that corresponds to a particular wavelength. In other words, the position of the first photodiode defines the above-described relationship which can be determined by calibration. For example, a light source having a known and fixed wavelength is used to determine the relationship that can be stored in the calibration means.

Alternatively or additionally, the optical detector device includes a second photodiode which is positioned to detect zeroth-order diffracted light. Optionally, the second photodiode is configured to measure an intensity of the zeroth-order diffracted light and to supply an inverse of the measured intensity to the analyser.

The second photodiode may be provided instead of the first photodiode. In this case the lack of intensity or minimal intensity of the modulated light is used to determine the wavelength. However, the first photodiode and the second photodiode may be simultaneously provided so that two measurements providing the same information are used. This increases the reliability and accuracy of the determination of the wavelength. The second photodiode may have to same characteristics and features as the first photodiode.

In an optional embodiment, the optical detector device includes an analog-to-digital converter.

The analog-to-digital converter (ADC) may be a device that converts an analog signal, such as the current generated by the optical detector device, into a digital signal which can be supplied or forwarded to the analyser. The analog-to-digital converter may convert an analog input voltage or current corresponding to the intensity of the light impinging onto the optical detector device to a digital number representing the magnitude of the voltage or current. The analyser is configured to process the digital signal generated by the analog-to-digital converter.

In an optional embodiment, the optical instrument further comprises a beam splitter and an optical detector configured to measure an intensity of received light and to supply the measured intensity to the analyser, wherein the beam splitter is configured to split incoming light in to a first path directed to the tunable optical filter device and a second path directed to the optical detector.

The optical detector may include one or more photodiodes and/or an optical sensor which are configured to measure the intensity of the light that impinges on the tunable optical filter device. To this end, a beam splitter or any other optical means for diverting or channeling off a beam of light is provided. This optical means is configured to re-direct an amount of light impinging onto the tunable optical filter device towards the optical detector. In other words, the beam splitter splits incoming light into the first path and the second path. The intensity of the light in the second path is significantly lower (for example 5%, 10%, or 20%) compared to the intensity of light in the first path. Further, the intensity of the light in the first path is directly proportional to the intensity of light in the second path so that measuring the intensity of the light in the second path is indicative of the intensity of light in the first path. The optical detector is used to determine the intensity of the light that impinges on the tunable optical filter device. This information may be used for calibrating the optical detector device and/or monitoring changes in the intensity of the light generated by the light source. The optical detector may be electrically or electronically connected or coupled to the analog-to-digital converter and/or to the analyser (e.g., via the analog-to-digital converter).

The second path may include optical components for redirecting, conveying and/or transmitting the light from the beam splitter to photodetector, such as mirrors, lenses and the like.

In an optional embodiment, the signal generator generates a plurality of identical modulation signals one after another for measuring the wavelength of the light at various points of time.

The plurality of identical modulation signals one after another can be considered a saw-tooth signal. This means that the parameter of modulation signal is repeatedly or periodically increased from a minimum value of the parameter (frequency) to a maximal value of the parameter (frequency), i.e., after reaching the maximum value, the modulation signal jumps back to the minimal value. The duration of the pulse of the light generated by the light source is preferably longer than 2 or more of the sweeps, i.e., the change of the modulation signal from the minimal value to maximal value. Each sweep can be used to measure the wavelength of the light source so that, with this embodiment, the wavelength of the light source can be determined at various points of time (e.g., several times during a pulse of the light source). If identical sweeps are used (e.g., a sawtooth profile), the wavelength of the light source can be determined at equally spaced apart points of time. The analyser may be configured to determine an average wavelength which correspond to the average of the various wavelength measured.

It is possible to correlate the sweep of the modulation signal to the pulse duration of the light source. For example, each sweep of the modulation signal may have approximately the same length as the pulse duration of the light source. Further, as outlined above, a plurality of sweeps of the modulation signal can be executed during one pulse of the light source.

In an optional embodiment, the signal generator generates the modulation signal after the generation of the trigger signal by a predetermined time lag for varying the point in time at which the wavelength of the light is determined.

In this embodiment, the calibration means may be configured to calibrate the measurements for each predetermined time lag. Changing the time lag provides a measurement of the wavelength of the light source at different points of time assuming that the pulses of the light source are highly correlated between each other. Repeating the measurements with the above-described sawtooth profile at various time lags can provide wavelength measurements over the pulse of the light source between the periodicity defined by the duration of the sweeps.

In an optional embodiment, the signal generator generates a plurality of identical modulation signals one after another for measuring the wavelengths of the light source at various points of time, wherein the signal generator generates a first modulation signal of the plurality of modulation signals after the generation of the trigger signal by a predetermined time lag.

This embodiment refers to the measurement of different wavelengths; the light source may include various lasers or LEDs having different wavelengths. In this case, the time lag can be used to identify the different wavelength in the analysis of the sweeps of the modulation signal. In other words, the different time lags make it possible to separate or filter the intensity peaks and determine the wavelength of each lasers and/or LEDs of the light source. The time lag is thus a time code with which lasers and/or LEDs of the light source are measured.

In an optional embodiment, the optical instrument further comprises a diffraction device configured to diffract light depending on its wavelength, wherein the diffraction device is positioned to diffract the light modulated by the tunable optical filter device.

The diffraction device is positioned in the light path between the tunable optical filter device and the optical detector device. The diffraction device is configured to divert modulated light differently depending on the wavelength, i.e., the angle of diversion changes depending on the wavelength. This may result in a spatial separation of the light modulated by the tunable optical filter device which then impinges on the optical detector device. In other words, the optical detector device may be configured to detect the light modulated by the tunable optical filter device at spatially separated locations. For example, the optical detector device may include a plurality of photodiodes each of which is spatially separated from each other and corresponds to a respective wavelength. Alternatively, the optical detector device may include a camera whereby the diffraction device provides a spatial resolution of the different wavelengths. Thus, the deflection device allows to simultaneously measure light from the light source having different wavelengths.

In an optional embodiment, the diffraction device is positioned to diffract the zeroth-order diffracted light and/or the first-order diffracted light. Further optionally, the diffraction device is a diffraction grating.

In an optional embodiment, the light source includes a laser and/or a light emitting diode (LED), wherein optionally the light source is configured to be run in continuous or pulsed operation.

In an optional embodiment, the light source includes a power driver configured to output a drive current to the laser and/or a light emitting diode (LED), the drive current controlling an output of the light.

The invention and its optional embodiments can be summarized as follows:

The principle of operation of the optical instrument can be to utilize the rapid sweeping of the AOTF filter function (modulation signal generated by the signal generator and fed to the tunable optical filter device) in time to rapidly measure the optical frequency of the light source or device-under-test (DUT) during a short period of time. The DUT or light source may be any type of optical device such as a laser, LED, etc. The DUT may be run in continuous or pulsed operation. Since the main advantage of some embodiments of this invention is for rapid detection of optical wavelength, the operation of this device in pulsed mode will be the focus of the description.

Light emitted from or transmitted through the DUT is optionally split using a beam splitter. This gives the option of measuring the amplitude/intensity using a fast photodiode while simultaneously measuring the optical frequency of the DUT. The main or first optical path will next pass through the tunable optical filter device or AOTF. Based on the optical frequency of light and acoustic frequency through the AOTF crystal or tunable optical filter device at a given instant, the light may either pass through the tunable optical filter device or AOTF undiffracted (0th order) or may be diffracted if the optical and acoustic frequencies match per the Bragg diffraction equation (1st order diffraction), or some combination of the two depending on the efficiency of the tunable optical filter device or AOTF. When the acoustic and optical frequency wave vectors match, the filter efficiency is at its greatest and as the acoustic frequency deviates from the optimum value, the tunable optical filter device or AOTF is less efficient. Therefore, by finding the optical peak of the 1st order diffraction intensity (or, alternatively, the trough of the 0th order diffraction) it is possible to determine the optical frequency if the acoustic frequency is known. Optionally, in this configuration, the 1st order diffraction is chosen to improve the Signal-to-Noise Ratio (SNR). This signal is collected using a photodiode and is measured using an analog-to-digital converter (ADC). The analog-to-digital converter, the photodiode for detecting first-order diffracted light, and the photodiode for detecting zeroth-order diffracted light may constitute an optical detector device. The optical detector device, in particular the analog-to-digital converter, may be connected or coupled to an analyser or performs the functions of the analyser. The signals input into the analog-to-digital converter can be considered inputs to the analyser.

Given that the optical frequency can be determined by matching it to an acoustic frequency traveling through the tunable optical filter device or AOTF, it becomes possible to use rapid acoustic frequency sweeps to locate the point of maximum efficiency of the filter, which in turn corresponds to the optical frequency of the light source or DUT. The acoustic drive frequency or modulation signal for the tunable optical filter device or AOTF may include a linear ramp (essentially a sinusoidal signal with monotonically increasing frequency) driven by a high accuracy arbitrary waveform generator, allowing for rapid frequency sweeps at high acoustic frequencies (greater than 1 GHz). As the acoustic frequency sweep approaches the point of maximum diffraction efficiency, the photodetector signal measuring the 1st order diffracted light will begin to rise until the optical and acoustic frequencies match the Bragg diffraction criterion and the momentum of the diffracted beam is matched by the sum of the momenta of the incident beam and the acoustic wave, resulting in the maximum of the 1st order beam. After this, the momenta of the incident and diffracted beam will not be perfectly matched by the momentum of the acoustic wave, so the optical and acoustic frequencies will diverge, and the signal will decrease.

Since the acoustic drive signal is quite rapid (typ. 50-200 MHz), the acoustic drive signal may not be measured directly. However, since the parameters of the frequency sweep are well defined, it is possible to instead know the frequency at any time by knowing the difference in the current time and the time at which the sweep started (e.g., a simple linear relationship). By extension, it is possible to know the acoustic frequency at which the maximum of the tunable optical filter device or AOTF response occurs by the difference in time between when the peak occurs (tₚₑₐₖ) and the start of the sweep (to).

Given that the principle of operation of the tunable optical filter device or AOTF can result in a 1:1 relationship between the frequency of maximum efficiency of the filter and a given optical frequency, a calibration curve between the peak of the filter function and the optical frequency can be obtained. Thus, given the delay between the start of the acoustic drive frequency sweep (modulation signal) and the maximum of the optical detector device or photodiode output from the first order of diffraction, and the sweep parameters, it is possible to get the instantaneous acoustic frequency of the maximum efficiency of the filter function. Given that parameter, the calibration curve provides the instantaneous optical frequency of the light source or DUT (within the uncertainty of the width of the filter function). This is the main principle of operation of this device.

A summary of the wavelength determination with regard to FIGS. 2 and 3 is as follows:
Waveform generator triggers data acquisition of photodiode output (bottom plot).
tₚₑₐₖ-t₀ is calculated using curve fit
Acoustic drive frequency is inferred from this delay as the waveform shape (and thereby instantaneous frequency) is known
Laser wavelength is inferred from calibration curve (above) from acoustic drive frequency at peak

Below is the description of optional methods to improve the utility of this optical instrument.

The above methodology can be extended to measure multiple points in time by repeating the measurements as needed. An example of such measurement is described for a pulsed light source or DUT. In this measurement, the acoustic frequency ramp is swept multiple times, resulting in a time sampling of the response of the light source or DUT. For example, the average delay of 100 optical signal peaks obtained for 100 laser pulses is translated to an average wavelength value and its 95% confidence interval for each frequency sweep window. The deviation from the steady state optical frequency can be calculated.

One limitation of the described approach is that the time resolution is determined by the length of the acoustic frequency sweep window. The sweep duration is limited by a number of factors, including the rise time of the tunable optical filter device or AOTF (typ. 4-10 microseconds), the sampling rate, and the spectral width of the tunable optical filter device or AOTF filter function. Thus, using it in the configuration described above, it is not possible to have arbitrarily fast sweeps. If the assumption is made (with a pulsed light source or DUT) that the pulses are highly correlated between each shot, it is possible to use a known delay to improve the time resolution of this method. For example, on the first pulse of the light source DUT the result might look like as described above. By delaying the onset of the acoustic frequency sweep a known amount, the filter responses will be shifted in time, thereby sampling a different segment in time of the pulsed tunable optical filter device or DUT frequency response. This can be repeated for a range of delays to measure the frequency response with high time resolution.

This embodiment of the invention can be summarized as follows: to further improve time resolution of this measurement, an initial delay can be used. In essence, the only time the frequency of the laser is being measured is near the peak of the tunable optical filter device or AOTF filter function. By offsetting the start of the data collection by a known amount, the laser pulse is effectively being sampled at different points during the laser pulse for each offset chosen.

Thereby, by taking the measurement over multiple laser pulses it is possible to interleave the data from each pulse to create a higher time resolution representation of the instantaneous frequency response of the laser during the pulse.

Heretofore the measurement of a single wavelength has been described, however this method can extend to the measurement of multiple wavelengths simultaneously as well. Due to the principle of linear independence of acoustic waves, it is possible to drive the tunable optical filter device or AOTF with acoustic signals which will simultaneously filter optical signals at disparate wavelengths. The advantage to this technique is two-fold, allowing for the detection of multiple wavelengths simultaneously or improving measurement throughput.

Using such a method, it is important to discriminate which laser of the light source corresponds to which filter function. This can be accomplished in two ways. The first embodiment is to use the timing of the sweeps to discriminate between wavelengths. Similar to the method described above to improve the throughput using discrete timing delays, the same idea can be used to discriminate between wavelengths; however, in this way by delaying the acoustic sweeps it is possible to separate the filter peaks and determine the instantaneous wavelength of each laser by time-encoding which laser is being measured.

An alternative embodiment utilizes a diffraction grating to separate each laser based on their operating wavelength. By spatially separating the output of each laser, it becomes possible to use an array of detectors (such as but not limited to a camera) to detect the response of each laser simultaneously.

### BRIEF DESCRIPTION OF THE DRAWINGS

Embodiments of the invention will now be described by way of example with reference to the accompanying drawings in which:

FIG. 1 is a is a block diagram of a light source and an optical instrument for determining a wavelength of the light source;

FIG. 2 shows time evolutions of a trigger signal, a parameter of a modulation signal, and a measured intensity as observed when operating the optical instrument of FIG. 1;

FIG. 3 shows a calibration curve of the optical instrument of FIG. 1;

FIG. 4 shows time evolutions of a laser pulse, a parameter of a modulation signal, and a measured intensity as observed when operating the optical instrument of FIG. 1 according to a second embodiment;

FIG. 5 shows the measured wavelength over time of the measurement according to FIG. 4;

FIG. 6 shows the measured wavelengths over time of the measurement according to FIG. 4;

FIG. 7 shows time evolutions of a laser pulse, a parameter of the modulation signal, and a measured intensity as observed when operating the optical instrument of FIG. 1 according to a third embodiment;

FIG. 8 shows the measured wavelength over time of the measurement according to FIG. 7;

FIG. 9 is a is a block diagram of a light source and an optical instrument for determining a wavelength of the light source according to a further embodiment;

FIG. 10 is a is a block diagram of a light source and an optical instrument for determining a wavelength of the light source according to a further embodiment; and

FIG. 11 is block diagram showing steps of a method for measuring a wavelength of a light source.

### DETAILED DESCRIPTION

The detailed description set forth below in connection with the appended drawings is intended as a description of exemplary embodiments of an optical instrument provided in accordance with the present invention and is not intended to represent the only forms in which the present invention may be constructed or utilized.

The present optical instrument 10 can be used to determine a wavelength of a light generated by light source 12. For example, the optical instrument 10 can be used to validate the correct functioning of the light source 12. The light source 12 includes a laser or LED 14, which can be a device-under-test (DUT), and a power driver 16. The power driver 16 generates a drive current for powering and controlling the laser or LED 14. The power driver 16 generates to drive current immediately after receiving a trigger signal from a signal generator 18.

The optical instrument 10 further includes a signal generator 18, a tunable optical filter device 20, an analyser 24, a beam splitter 26, and/or an optical detector 28. The tunable optical filter device 18 may include an acousto-optic tunable filter (AOTF) and is positioned to receive the light generated by the laser 14. The tunable optical filter device 18 is electrically or electronically connected to the signal generator 18. The tunable optical filter device 18 is configured to diffract impinging light depending on a modulation signal received from the signal generator 18. In other words, the signal generator 18 generates the modulation signal based on which the light is modulated by the tunable optical filter device 20. For example, if a parameter of the modulation signal is a particular value, the intensity of them modulated (diffracted) light is highest resulting, for example, in a maximum in the first order diffraction. This can be detected by optical detector device 22 which includes one or more photodiodes. For example, a first photodiode is configured to detect the intensity of the first-order diffracted light and a second photodiode is configured to detect the intensity of the zeroth-order. A maximum in the intensity detected by the first photodiode and a minimum in the intensity detected by the second photodiode indicate that the current parameter of the modulation signal corresponds to the wavelength generated by the light source 12.

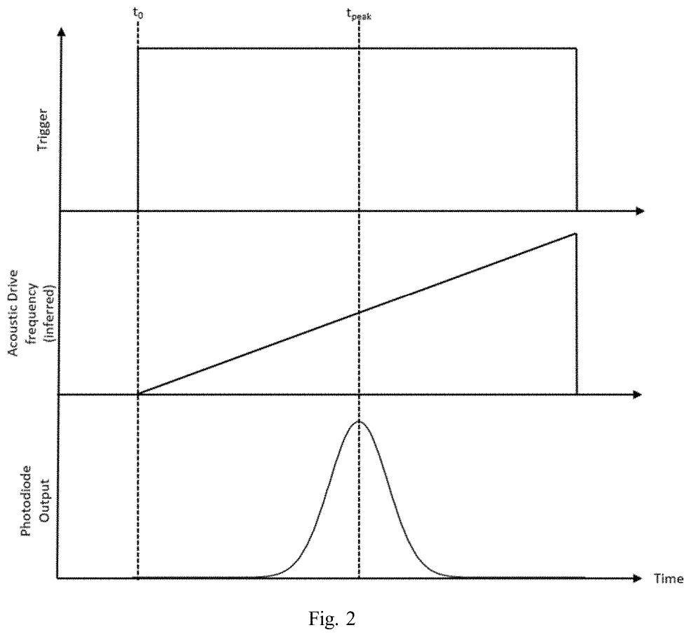

The signal generator 18 continuously varies the parameter of the modulation signal which may be the frequency of a carrier wave as long as the light source 12 generates light (see FIG. 2). For example, the signal generator 18 generates a sweep of the frequency from a minimum frequency to a maximum frequency (see middle graph of FIG. 2). This sweep of the frequency results in a change of detected intensity which reaches a maximum at the first photodiode (see lower graph of FIG. 2) and a corresponding minimum at the second photodiode.

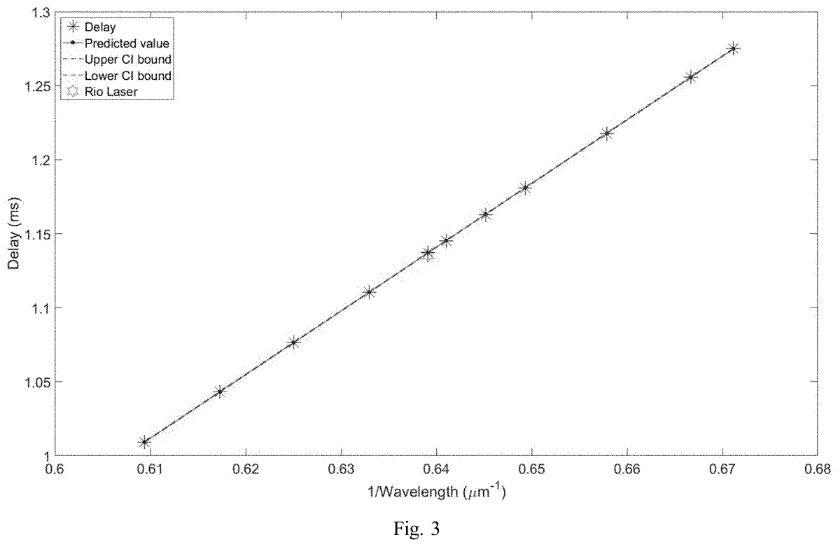

Alternatively, the signal generator 18 generates a trigger signal which is forwarded to the analyser 24. The time since the receipt of the trigger signal which also starts to sweep of the modulation signal can be used to determine the current value of the modulation signal such as the current frequency of the acoustic wave generated by tunable optical filter device 24 for modulating or diffracting the light generated by the light source 12. If the time that has passed since the receipt of the trigger signal is stored in relation to known wavelengths during a calibration (see FIG. 3), this relationship can be used to determine the wavelength of the light source 12. To this end, the analyser 24 determines when the intensity of the signal generated by the first photodiode is maximal and/or the intensity of the signal generated by the second photodiode is minimal. The relationship is then used to determine the wavelength based on this point of time.

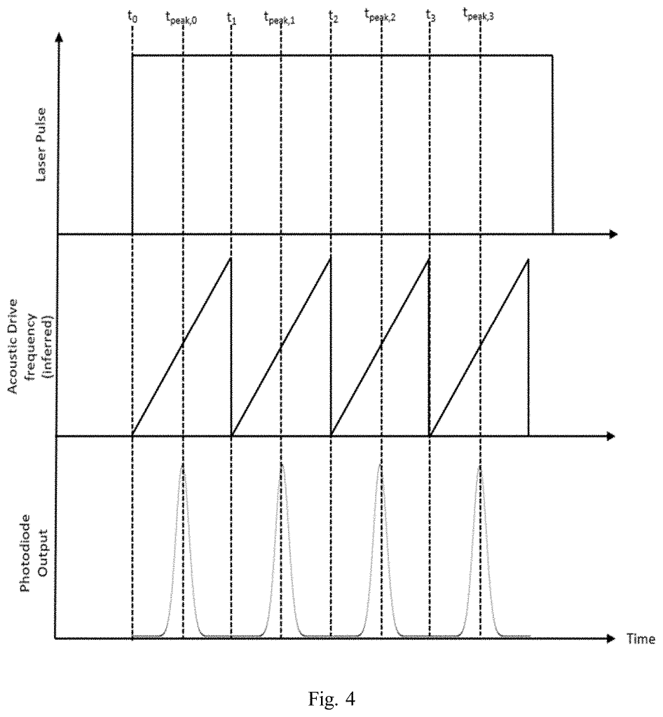

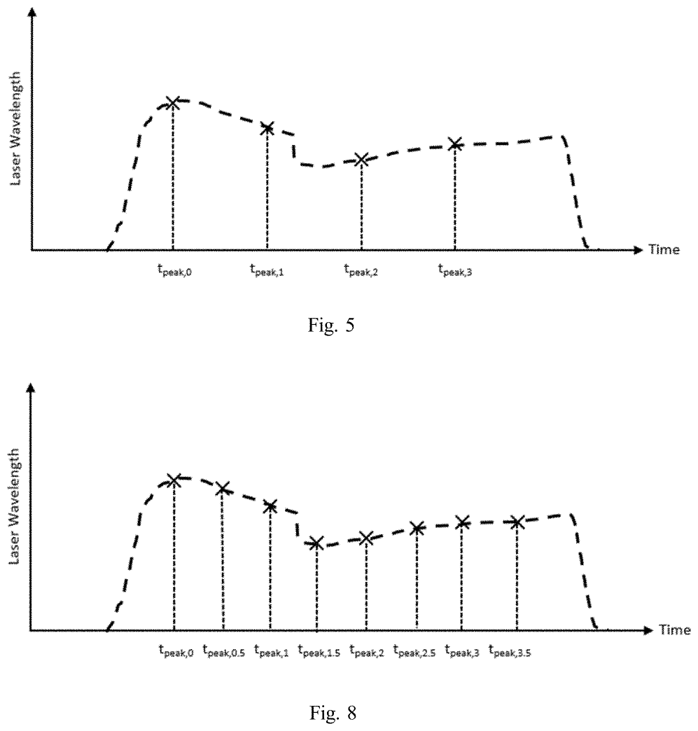

In a different embodiment, the signal generator 18 may be configured to repeatedly generate a sweep of the parameter of the modulation signal resulting in a saw-tooth profile of the parameter of the modulation signal (see middle graph in FIG. 4). In this way, the wavelength can be determined at various points of the times during the generational slide of the light source 12. This allows an observation of a temporal behaviour of the wavelength (see FIG. 5).

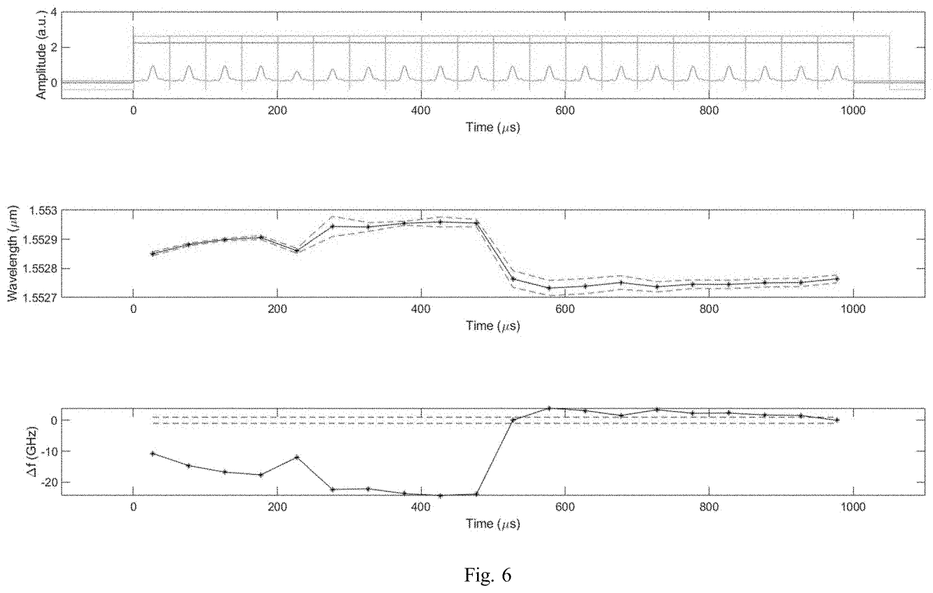

FIG. 6 shows an actual measurement result, whereby the average delay of 100 optical signal peaks obtained for 100 laser pulses (upper graph) is translated to an average wavelength value and its 95% confidence interval for each frequency sweep window (middle graph). The deviation from the steady state optical frequency is shown in the lower graph.

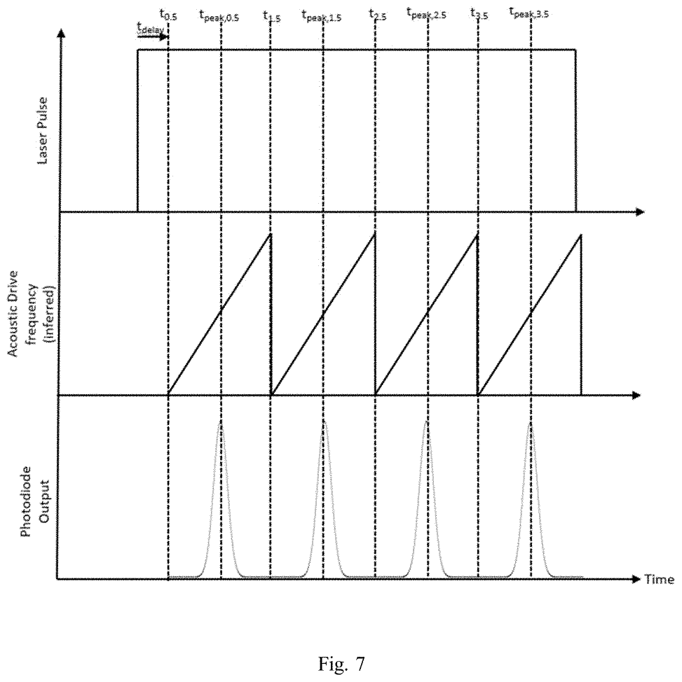

The temporal distance between the point of time when wavelength can be determined (i.e. the periodicity of the measurement) depends on the duration of the sweep which can be determined by external factors such as the rise time of the tunable optical filter device 20. In order to provide wavelength measurements between those points of time, the start of the first sweep of the plurality of sweeps may be delayed by a predetermined delay time (see FIG. 7). By varying the delay time and repeating the measurement of FIG. 4, more measurements of the wavelength over the same time range can be achieved (see FIG. 8).

The beam splitter 26 splits the light generated by light source 12 into a first path which leads to the optical tunable optical filter device 20 and a second part which leads to the optical detector 28. The optical detector 28 includes a photodiode and is configured to measure the intensity of the light generated by the light source 12. The optical detector 28 is electrically connected to the analyser 24. This allows to measure the intensity of the light generated by the light source and address potential changes in the intensity.

The analyser 24 may include a microprocessor and a memory unit is further electrically coupled to the optical detector device 22. The analyser 24 may include a functional unit characterised as a calibration means which allows recording and storing the relationship as shown in FIG. 3.

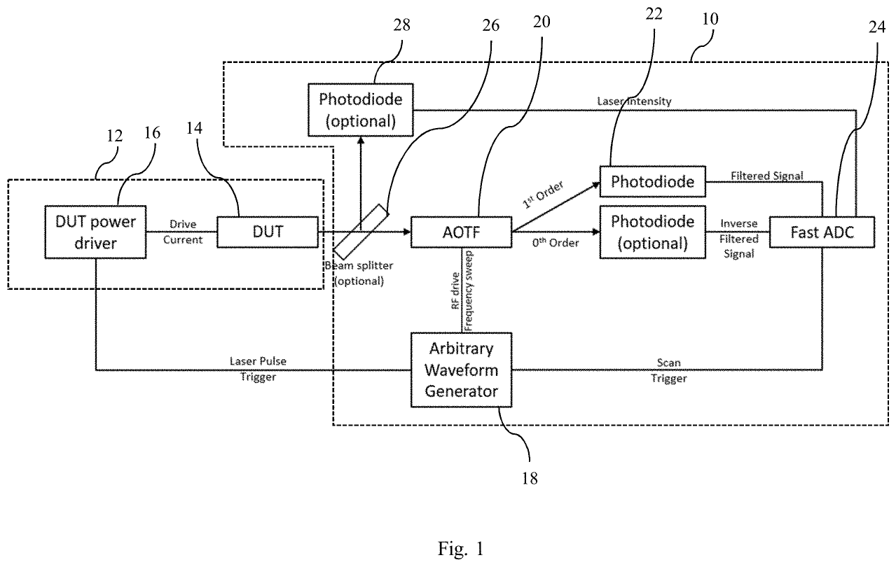

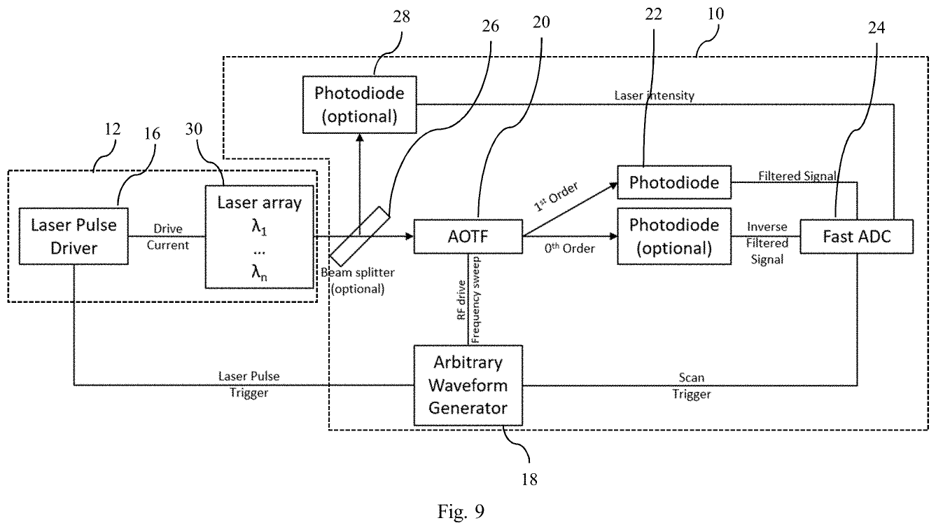

The embodiment of FIG. 9 includes the same features and characteristics as the embodiment of the optical instrument 10 of FIG. 1. The embodiment of FIG. 9 differs from the embodiment of FIG. 1 in that the light source 12 includes a laser array 30 instead of the laser 14. The laser array 30 is configured to provide light having multiple wavelengths. As the laser array 30 provides light of several wavelengths, the optical instrument 10 needs to be able to determine which wavelength is measured or, in other words, which laser of the laser array 30 corresponds to which filter function or parameter of the modulation signal. The intensity peaks detected at the first photodiode of the light source 12 can be resolved using the method of FIG. 7, i.e. by varying the delay time. In other words, the time delay is a way of encoding which laser of the laser array 30 is being measured.

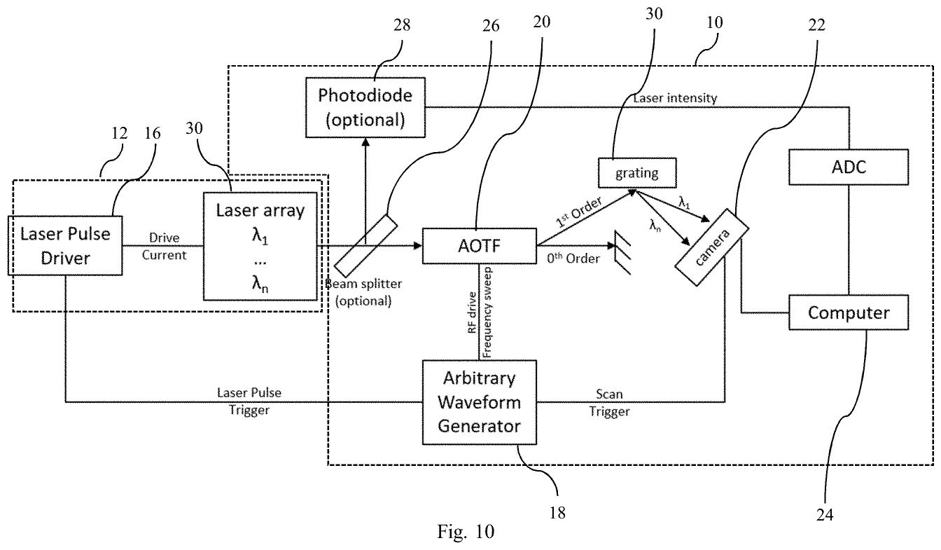

The embodiment of FIG. 10 includes the same features and characteristics as the embodiment of FIG. 9. The embodiment of FIG. 10 differs from the embodiment of FIG. 9 in that the optical instrument 10 includes a diffraction device 32 such as a grating. The diffraction device 32 is positioned between the tunable optical filter device 20 and the optical detector device 20. The diffraction device 32 is provided to spatially separate the modulated light depending on its wavelength. This allows to simultaneously measure the intensity of the modulated light at several frequencies. In this case, the optical detector device 22 includes array of detectors (such as but not limited to a camera) to detect the response of each laser of the laser array 30 simultaneously.

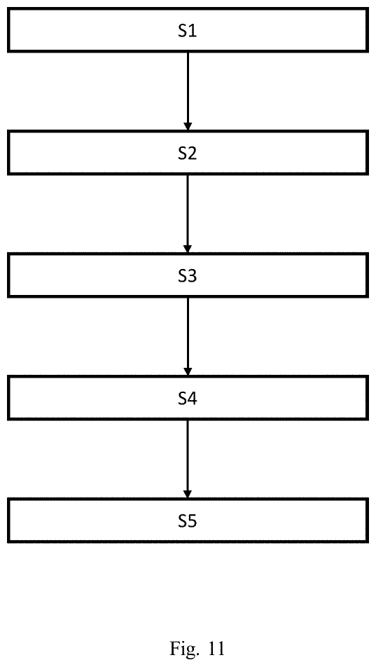

As method for measuring the wavelength of the light source 12 is described with reference to FIG. 11. In step S1, the relationship between the wavelength and the time delay since the start of the modulation signal is recorded. For this calibration step, various laser source having known and fixed wavelength are used with the optical instrument 10 described above. The time point of maximum intensity for the first-order diffraction is recorded. All the recorded time points are input into the relationship. In step S2, the light source 12 (as described above) or DUT is coupled to the optical instrument 10 and the modulation signal is generated by the signal generator 18 (as described above). In step S3, the tunable optical filter device 20 modulates the light by the light source 12 depending on the modulation signal, for example diffracts the light. In step S4, the optical detector device 22 measures the intensity of the modulated light and forwards the intensity to the analyser 24. In step S5, the analyser 24 determines the point of time since the receipt of the modulation signal when the measured intensity is maximal. The analyser 24 uses the stored relationship and the determined point of time to determine the wavelength of the light source 12.

What is claimed is:

1. An optical instrument for determining a wavelength of light generated by a light source, comprising
a signal generator for generating a modulation signal,
a tunable optical filter device configured to receive the modulation signal, the tunable optical filter device configured to modulate the light generated by the light source based on the modulation signal,
an optical detector device configured to detect a degree of modulation of the light modulated by the tunable optical filter device, and
an analyser configured to determine the wavelength of the light based the degree of modulation.

2. The optical instrument of claim 1, wherein the tunable optical filter device includes an acousto-optic tunable filter (AOTF).

3. The optical instrument of claim 1 or 2, wherein the tunable optical filter device is configured to diffract the light generated by the light source based on the modulation signal.

4. The optical instrument of any preceding claim, wherein the signal generator generates the modulation signal which includes a sweep of a parameter of the modulation signal for determining the wavelength of the light, wherein the degree of modulation by the tunable optical filter device is highest if the wavelength of the light corresponds to a particular value of the parameter of the modulation signal.

5. The optical instrument of any preceding claim, wherein the signal generator generates the modulation signal which is a frequency-modulated wave whose frequency is swept from a minimum frequency to a maximum frequency.

6. The optical instrument of claim 5, wherein a nominal frequency of the wave is greater than 1 GHz and/or a frequency of the sweep is between 50 MHz to 200 MHz.

7. The optical instrument of any preceding claim, wherein the signal generator includes an arbitrary waveform generator.

8. The optical instrument of any preceding claim, wherein the signal generator is configured to generate a trigger signal simultaneous to the generation of the modulation signal for indicating a start of the modulation signal.

9. The optical instrument of any preceding claim, wherein the signal generator is configured to be coupled to the light source, the signal generator configured to supply the trigger signal to the light source for starting the generation of a light pulse.

10. The optical instrument of any preceding claim, wherein the signal generator is coupled to the analyser for supplying the trigger signal to the analyser.

11. The optical instrument of any preceding claim, wherein the analyser includes a calibration means configured to store a relationship between the wavelength of a light and the time since the generation of the trigger signal.

12. The optical instrument of claim 11, wherein the relationship is linear function.

13. The optical instrument of any preceding claim, wherein the optical detector device includes a first photodiode which is positioned to detect first-order diffracted light.

14. The optical instrument of claim 13, wherein the first photodiode is configured to measure an intensity of the first-order diffracted light and to supply the measured intensity to the analyser.

15. The optical instrument of any preceding claim, wherein the optical detector device includes a second photodiode which is positioned to detect zeroth-order diffracted light.

16. The optical instrument of claim 15, wherein the second photodiode is configured to measure an intensity of the zeroth-order diffracted light and to supply an inverse of the measured intensity to the analyser.

17. The optical instrument of any preceding claim, wherein the optical detector device includes an analog-to-digital converter.

18. The optical instrument of any preceding claim, further comprising a beam splitter and an optical detector configured to measure an intensity of received light and to supply the measured intensity to the analyser, wherein the beam splitter is configured to split incoming light in to a first path directed to the tunable optical filter device and a second path directed to the optical detector.

19. The optical instrument of claim 18, wherein the optical detector includes a photodiode.

20. The optical instrument of any preceding claim, wherein the signal generator generates a plurality of identical modulation signals one after another for measuring the wavelength of the light at various points of time.

21. The optical instrument of any preceding claim, wherein the signal generator generates the modulation signal after the generation of the trigger signal by a predetermined time lag for varying the point in time at which the wavelength of the light is determined.

22. The optical instrument of any preceding claim, wherein the signal generator generates a plurality of identical modulation signals one after another for measuring the wavelengths of the light source at various points of time, wherein the signal generator generates a first modulation signal of the plurality of modulation signals after the generation of the trigger signal by a predetermined time lag.

23. The optical instrument of any preceding claim, further comprising a diffraction device configured to diffract light depending on its wavelength, wherein the diffraction device is positioned to diffract the light modulated by the tunable optical filter device.

24. The optical instrument of claim 23, wherein the diffraction device is positioned to diffract the zeroth-order diffracted light and/or the first-order diffracted light.

25. The optical instrument of claim 23 or 24, wherein the diffraction device is a diffraction grating.

26. The optical instrument of any preceding claim, wherein the optical detector device is configured to detect the light modulated by the tunable optical filter device at spatially separated locations.

27. The optical instrument of any preceding claim, wherein the optical detector device includes a camera or a plurality of photodiodes.

28. An optical system, comprising
the optical instrument of any preceding claims, and
a light source generating light which is input into the tunable optical filter device.

29. The optical system of claim 28, wherein the light source includes a laser and/or a light emitting diode (LED), wherein optionally the light source is configured to be run in continuous or pulsed operation.

30. The optical system of claim 29, wherein the light source includes a power driver configured to output a drive current to the laser and/or a light emitting diode (LED), the drive current controlling an output of the light.

31. A method for determining a wavelength of light generated by a light source, comprising the steps of
generating a modulation signal,
modulating the light generated by the light source based on the modulation signal,
detecting a degree of modulation of the modulated light, and
determining the wavelength of the light based on the degree of modulation.

32. The method of claim 31, wherein the light is modulated by a tunable optical filter device, optionally by an acousto-optic tunable filter (AOTF).

33. The method of claim 31 or 32, wherein the light is modulated by diffracting the light based on the modulation signal.

34. The method of any one of the claims 31 to 33, wherein the modulation signal includes a sweep of a parameter of the modulation signal for determining the wavelength of the light, wherein the degree of modulation is highest if the wavelength of the light corresponds to a particular value of the parameter of the modulation signal.

35. The method of any one of the claims 31 to 34, wherein the modulation signal is a frequency-modulated wave whose frequency is swept from a minimum frequency to a maximum frequency.

36. The method of claim 35, wherein a nominal frequency of the wave is greater than 1 GHz and/or a frequency of the sweep is between 50 MHz to 200 MHz.

37. The method of any one of the claims 31 to 36, wherein the modulation signal is generated by an arbitrary waveform generator.

38. The method of any one of the claims 21 to 37, further comprising a step of generating a trigger signal simultaneous to the generation of the modulation signal for indicating a start of the modulation signal.

39. The method of claim 38, wherein the trigger signal is supplied to the light source for starting the generation of a light pulse.

40. The method of any one of the claims 31 to 39, further comprising a step of storing a relationship a relationship between the wavelength of a light and the time since the generation of the trigger signal.

41. The method of claim 40, wherein the relationship is linear function.

42. The method of claim 40 or 41, further comprising determining the wavelength of the light generated by the light source using the relationship.

43. The method of any one of the claims 31 to 42, wherein the step of detecting the degree of modulation of the modulated light includes detecting first-order diffracted light.

44. The method of claim 43, wherein the step of detecting the degree of modulation of the modulated light includes measuring an intensity of the first-order diffracted light, wherein the step of determining the wavelength is based on the measured intensity of the first-order diffracted light.

45. The method of any one of the claims 31 to 44, wherein the step of detecting the degree of modulation of the modulated light includes detecting zeroth-order diffracted light.

46. The method of claim 47, wherein the step of detecting degree of modulation of the modulated light includes measuring an intensity of the zeroth-order diffracted light, wherein the step of determining the wavelength is based on an inverse of the measured intensity of the zeroth-order diffracted light.

47. The method of any one of the claims 31 to 46, wherein the step of detecting the degree of modulation of the modulated light includes using an analog-to-digital converter.

48. The method of any one of the claims 31 to 47, further comprising a step of splitting light coming from the light source into a first path which is modulated based on the generated modulation signal and a second path, wherein an intensity of the light of the second path is measured.

49. The method of claim 48, wherein the intensity of light of the second path is measured by a photodiode.

50. The method of any one of the claims 31 to 49, wherein a plurality of identical modulation signals is generated one after another for measuring the wavelength of the light at various points of time.

51. The method of any one of the claims 31 to 50, wherein the modulation signal is generated after the generation of the trigger signal by a predetermined time lag for varying the point in time at which the wavelength of the light is determined.

52. The method of any one of the claims 31 to 51, wherein a plurality of identical modulation signals is generated one after another for measuring the wavelengths of the light source at various points of time, wherein a first modulation signal of the plurality of modulation signals is generated after the generation of the trigger signal by a predetermined time lag.

53. The method of any one of the claims 31 to 52, further comprising a step of additionally diffracting the modulated light depending on its wavelength.

54. The method of claim 53, wherein the zeroth-order diffracted light and/or the first-order diffracted light is additionally diffracted.

55. The method of claim 53 or 54, wherein a diffraction grating is used for additionally diffracting the modulated light.

56. The method of any one of the claims 33 to 55, wherein the step of determining the wavelength includes detecting the modulated light at spatially separated locations.

57. The method of any one of the claims 33 to 56, wherein the step of determining the wavelength includes using a camera or a plurality of photodiodes.
